(19) United States
(12) Patent Application Publication
(10) Pub. No.: US 2010/0039684 A1
(43) Pub. Date: Feb. 18, 2010

(54) SENSITIZER DYES FOR PHOTOACID GENERATING SYSTEMS USING SHORT VISIBLE WAVELENGTHS

(76) Inventors: Eric S. Kolb, Acton, MA (US); Kirk D. Hutchinson, Sudbury, MA (US); David A. Waldman, Concord, MA (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 12/310,126

(22) PCT Filed: Aug. 10, 2007
(86) PCT No.: PCT/US2007/017749

§ 371 Date: Oct. 28, 2009

Related U.S. Application Data
(60) Provisional application No. 60/837,168, filed on Aug. 12, 2006.

(51) Int. Cl. G03H 1/02; G03F 7/00

(52) U.S. Cl. 359/3; 430/2

(57) ABSTRACT

Photosensitizing dyes are often used in conjunction with a photoacid generator in photopolymerizable materials and in holographic recording media. Typical dyes for these materials are used in the region of the visible spectrum for wavelengths greater than about 450 run. The present invention discloses a number of new 1,4-alkynyl substituted napthalene photosensitizing dyes that have suitably low extinction coefficients coupled with good sensitizing properties for use in such materials at wavelengths in the visible spectrum region of about 400 nm.

### RELATED APPLICATION

This application claims the benefit of the U.S. Provisional Application No. 60/837,168, filed on Aug. 12, 2006. The entire content of this application is incorporated herein by reference.

### BACKGROUND OF THE INVENTION

Photoacid generation has become valuable in the fields of photoresists and cationic polymerization for applications, such as coatings, composites, optical storage media, etc. Cationic photopolymerization has developed into an excellent alternative to free-radical photopolymerization for applications that can take advantage of the high speed, low temperature, and environmental friendliness of radiation curing technology. In contrast with radiation curing processes initiated by free radicals, cationic photopolymerization processes are not inhibited by oxygen, and by employing monomers and oligomers such as epoxides and oxetanes that undergo rapid cationic ring opening polymerization (CROP), shrinkage resulting from polymerization can be dramatically reduced. Since the onium salt photoacid generators (PAGs) that are commonly used to initiate cationic photopolymerization are typically sensitive only to ultraviolet light when irradiated directly, photosensitizer dyes are used in conjunction with the PAGs to enable photoinitiated acid generation and cationic photopolymerization at longer wavelengths in the visible spectral regions. However, there is a need for sensitizer dyes to be used with PAGs in the short visible (violet) spectral band.

### SUMMARY OF THE INVENTION

This invention provides a series of novel 1,4-alkynyl substituted naphthalene dyes. This invention further provides such dyes that are efficient photosensitizes for onium salt photoacid generators (PAGs) when exposed to actinic radiation, and, further, can be used as initiator systems in photopolymerizable materials. Additionally, such dyes further exhibit desirable absorbance in the short-wavelength visible spectrum, 400-430 nm. This invention also provides a process or method for the utilization of these dyes for the recording of holograms with good recording sensitivity and good image fidelity. The photosensitizer dyes of this invention also preferably completely bleach upon exposure to light when used in combination with a photoacid generator.

The present invention includes a dye represented by Structural Formula (I):

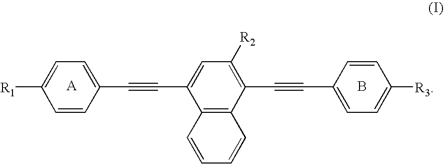

In Structural Formula (I), R₁ and R₃, are each independently —H, a halogen, a substituted or unsubstituted alkyl group, a substituted or unsubstituted alkenyl group, a substituted or unsubstituted alkoxy group, a substituted or unsubstituted aryl group or a substituted or unsubstituted heteroaryl group or —Si(R₅)₃; R₂ is —H, a substituted or unsubstituted alkyl group, a substituted or unsubstituted alkenyl group, a substituted or unsubstituted alkoxy group, a substituted or unsubstituted aryl group, a substituted or unsubstituted heteraryl group, or —Si(R₅)₃; and R₅ is a substituted or unsubstituted alkyl group or a substituted or unsubstituted aryl group or a substituted or unsubstituted heteroaryl group.

In one embodiment, the compound of formula (I) is not the compound represented by structural formula (III):

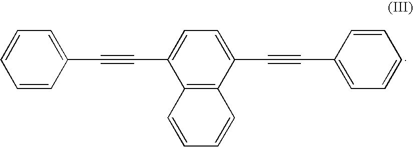

Ring A and ring B, in addition to R₁ or R₃, are each independently further optionally substituted with one or more substituents selected from the group consisting of halogen, substituted or unsubstituted alkyl, substituted or unsubstituted alkoxy, and trialkylammonium and diarylamino groups, wherein each alkyl, and each aryl is independently optionally substituted.

In another embodiment, the present invention is a polymerizable medium, comprising:
a) a dye disclosed herein;
b) a compound, referred to as a “PAG,” which in combination with said dye produces acid when exposed to actinic radiation; and
c) at least one monomer or oligomer which is capable of undergoing cationic polymerization initiated by said acid.

One type of polymerizable medium is a holographic recording medium (HRM), where the medium comprises:
a) a dye (e.g., dyes which can sensitize photoacid generating compounds);
b) a compound, referred to as a “PAG,” which in combination with said dye produces acid when exposed to actinic radiation;
c) a monomer or oligomer which is capable of undergoing cationic polymerization initiated by said acid; and
d) a binder that is capable of supporting cationic polymerization of the monomer or oligomer.

The medium is advantageously greater than about 300 μm thick.

The present invention also includes a method of generating acid, comprising the step of exposing to visible light a composition comprising:
a) a dye disclosed herein; and
b) a compound, referred to as a photoacid generator (PAG), which in combination with said dye produces acid when exposed to actinic radiation.

In another aspect, the present invention is a method of recording holograms within a holographic recording medium disclosed herein. The method generally comprises the step of passing into the medium a reference beam of coherent actinic radiation and at substantially the same location in the medium simultaneously passing into the medium an object beam of the same coherent actinic radiation, thereby forming within the medium an interference pattern, wherein the dye disclosed herein, in combination with the PAG, produces acid upon exposure to the actinic radiation in the reference and object beams, thereby recording a hologram within the medium.

Advantages of the present invention include photosensitizer dyes with low extinction coefficients when exposed to visible light and tailored for an exposure wavelength of about 400 to 410 nm. As a consequence, holographic recording media sensitized to wavelengths near 400 nm and having a thickness greater than about 300 micrometers, and which exhibit good recording sensitivity and good image fidelity, can be prepared with these dyes. These photosensitizer dyes also preferably bleach upon exposure to visible light when in the presence of a photoacid generator.

### BRIEF DESCRIPTION OF FIGURES

FIG. 1 shows recording sensitivity and cumulative grating strength as a function of cumulative exposure fluence for a holographic recording material of thickness, T=300 microns.

FIG. 2 shows recording sensitivity and cumulative grating strength as a function of cumulative exposure fluence for a holographic recording material comprising a naphthalene dye (sensitizer) of the present invention of thickness, T=400 microns.

### DETAILED DESCRIPTION OF THE INVENTION

The present invention relates to a new class of 1,4-alkynyl substituted naphthalene photosensitizing dyes, which can sensitize onium salt photoacid generators (“PAGs”) when exposed to visible light.

In one embodiment, the present invention is a compound of formula (I):

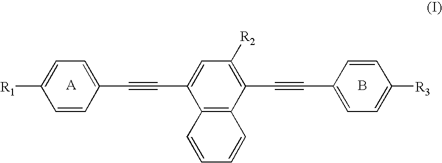

In Structural. Formula (I):

R₁ and R₃, are each independently —H, a halogen, a substituted or unsubstituted alkyl or cycloalkyl group, a substituted or unsubstituted alkenyl or cycloalkenyl group, a substituted or unsubstituted alkoxy group, a substituted or unsubstituted aryl group or a substituted or unsubstituted heteroaryl group or —Si(R₅)₃; preferably, R₁ and R₃, are each independently —H, C1-C12 alkyl or C3-C10 cycloalkyl, C1-C12 halogenated alkyl, C1-C12 alkoxy, benzyl or phenyl; more preferably, R₁ and R₃, are each independently —H, methyl, ethyl, 2-ethylhexyl, C1-C12 fluorinated or perfluorinated alkyl, methoxy, ethoxy, 2-ethylhexyloxy, chloro, trifluoromethyl or cyclohexyl; even more preferably, R₁ and R₃, are each independently —H or —OCH₃.

R₂ is —H, a substituted or unsubstituted alkyl group or cycloalkyl group, a substituted or unsubstituted alkenyl or cycloalkenyl group, a substituted or unsubstituted alkoxy group, a substituted or unsubstituted aryl group, a substituted or unsubstituted heteroaryl group, or —Si(R₅)₃; preferably, R₂ is —H, C1-C12 alkyl or C3-C10 cycloalkyl, C1-C12 halogenated alkyl, C1-C12 alkoxy, benzyl, phenyl, or —Si(R₅)₃; more preferably, R₂, is —H, methyl, ethyl, 2-ethylhexyl, C1-C12 fluorinated or perfluorinated alkyl, methoxy, ethoxy, 2-ethylhexyloxy, trifluoromethyl, cyclohexyl or —Si(R₅)₃; even more preferably, R₂ is —H or OCH₃.

Each R₅ is a substituted or unsubstituted alkyl group or a substituted or unsubstituted aryl group or a substituted or unsubstituted heteroaryl group; preferably, R₅ is C1-C12 alkyl, C3-C10 cycloalkyl, phenyl or benzyl; more preferably, R₅ is methyl, ethyl, 2-ethylhexyl, cyclohexyl, benzyl or phenyl.

Ring A and ring B in formula (I), in addition to R₁ or R₃, are each independently further optionally substituted with one or more substituents selected from the group consisting of halogen, substituted or unsubstituted alkyl, substituted or unsubstituted alkoxy, and trialkylammonium and diarylamino groups, wherein each alkyl and each aryl is independently optionally substituted.

Preferably, alkyl groups of trialkylammonium are straight, branched or cyclic C1-C12 alkyls. Optional substituents on alkyl groups of trialkylammonium are selected from C1-C12 alkyl, C1-C12 halogenated alkyl; C3-C10 cycloalkyl, phenyl, benzyl, or C1-C12 alkoxy, optionally substituted with C1-C6 alkyl or C1-C6 haloalkyl or C3-C10 cycloalkyl. More preferably, the substituents on aryl and alkyl groups of trialkylammonium and diarylamino are methyl, ethyl, 2-ethylhexyl, C1-C12 fluorinated or perfluorinated alkyl, cyclohexyl, benzyl, phenyl, OCH₃, 2-ethylhexyloxy, or trifluoromethyl.

Preferably, aryl groups of diarylamino groups are phenyls. Optional substituents on aryl groups of diarylamino group are C1-C12 alkyl, C1-C12 halogenated alkyl, C3-C10 cycloalkyl, halogen, phenyl or benzyl, or C1-C12 alkoxy, optionally substituted C1-C6 alkyl or C1-C6 haloalkyl or C3-C10 cycloalkyl. More preferably, the substituents on aryl groups of diarylamino group are methyl, ethyl, 2-ethylhexyl, C1-C12 fluorinated or perfluorinated alkyl, cyclohexyl, benzyl, phenyl, 2-ethylhexyloxy, —OCH₃, chloro, or trifluoromethyl.

In one embodiment, the compound of formula (I) is not the compound of formula (III):

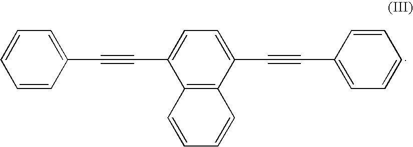

One preferred dye of formula (I) is represented by Structural Formula (II):

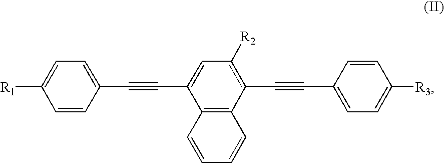

In formula (II), values and preferred values of variable R₁, R₂, and R₃ are as defined above for formula (I).

In one embodiment, the compound of formula (I) is a compound of formula (II) wherein R₂ is —H or a substituted or unsubstituted alkoxy group and R₁ and R₃ are as described in formula (I). In another embodiment, the compound is represented by formula (II), wherein R₁ and R₃ are —H or a substituted or unsubstituted alkoxy group and R₂ is as described in formula (I).

In another embodiment, the compound is represented by formula (II), wherein R₁ and R₃ are —H or a substituted or unsubstituted alkoxy group, and R₂ is —H. In another embodiment, the compound is represented by formula (II), wherein R₁ and R₃ are —H or a substituted or unsubstituted alkoxy group, and R₂ is —OCH₃.

In one embodiment, the present invention is a compound of formula (I) or formula (II), wherein the compound has an extinction coefficient less than 16,000 L mol⁻¹ cm⁻¹ at 405 nm. Preferably, the compound of formula (I) or formula (I) has an extinction coefficient less than 12,000 L mol⁻¹ cm⁻¹ at 405 nm. Even more preferably, the compound of formula (I) or formula (II) has an extinction coefficient less than 6,000 L mol⁻¹ cm⁻¹ at 405 nm.

In one embodiment of formula (II), R₂ is —H or a substituted or unsubstituted alkoxy group, preferably a substituted or unsubstituted alkoxy group, more preferably a methoxy group and R₁ and R₃ are as described above for formula (II). In another embodiment, R₂ is —H or —OCH₃ and R₁ and R₃ are as described above for formula (II).

In another embodiment, R₁ and R₃ in formula (II) are —H or a substituted or unsubstituted alkoxy group, preferably a substituted or unsubstituted alkoxy group, more preferably a methoxy group and R₂ is as described for formula (II) (e.g., —OCH₃). In another embodiment, R₁ and R₃ in formula (II) are —H or —OCH₃ and R₂ is as described for formula (II).

In another embodiment, the dye is represented by formula (II), wherein R₁, R₂ and R₃ are independently —H or a substituted or unsubstituted alkoxy group. Preferably, R₁, R₂ and R₃ are independently a substituted or unsubstituted alkoxy group. More preferably, R₁, R₂ and R₃ are each methoxy group.

One embodiment of compounds of formula (I) is represented by the formula (III):

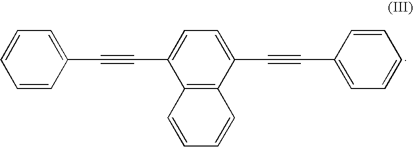

Another preferred dye is represented by formula (IV):

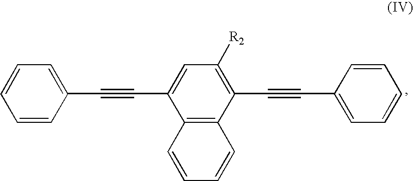

wherein R₂ is a substituted or unsubstituted alkoxy group, preferably a methoxy group.

Even more preferably, the dye is represented by Structural Formula (V):

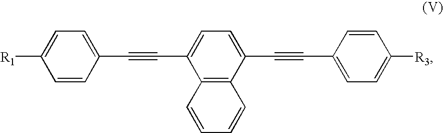

wherein R₁ and R₃ are independently a substituted or unsubstituted alkoxy group, preferably a methoxy group.

Photosensitizing dyes of the present invention can be used to sensitize “PAGs” such as iodonium, sulfonium, diazonium, or phosphonium salts to produce acid when exposed to actinic radiation. Most commonly, iodonium or sulfonium salts are used. Suitable iodonium salts include, but are not limited to, (4-octyloxyphenyl)phenyliodonium hexafluoroantimonate, ditolyliodonium tetrakis(pentafluorophenyl)borate, diphenyliodonium tetrakis(pentafluorophenyl)borate, tolylphenyliodonium tetrakis(pentafluorophenyl)borate, cumyltolyliodonium tetrakis(pentafluorophenyl) borate, di(4-t-butylphenyl)iodonium tris(trifluoromethylsulfonyl)methylate, dicumyliodonium tetrakis(3,5-bistrifluoromethylphenyl)borate, di(4-1-butylphenyl) iodonium tetrakis(3,5-bistrifluoromethylphenyl)borate and cumyltolyliodonium tetrakis(3,5-bistrifluoromethylphenyl)borate. Other suitable “PAGs” include sulfonium salts such as those disclosed in U.S. Patent Publication No. 2005/0059543 and PCT publication WO2004/058699, entitled FLUOROARYLSULFONIUM PHOTOACID GENERATORS, the entire teachings of which are incorporated herein by reference.

Photosensitizer dyes of the present invention advantageously have extinction coefficients in the visible region, for example, at wavelengths of commercially available solid state diode lasers such as emitting between 400 and 410 nm, of less than 16,000 L mol⁻¹ cm⁻¹, preferably less than 10,000 L mol⁻¹ cm⁻¹, more preferably less than 6,000 L mol⁻¹ cm⁻¹, and even more preferably less than 2,000 L mol⁻¹ cm⁻¹.

It is advantageous to increase the thickness of a photopolymerizable holographic recording medium, for example, to increase the amount of information contained per unit area. The medium is advantageously greater than 300 μm thick, greater than 500 μm thick, greater than 1,000 μm thick or greater than 2,000 μm thick. For example, a medium can be greater than 300 μm thick and less than 1000 μm thick, greater than 500 μm thick and less than 1000 μm thick, greater than 1000 μm thick and less than 2000 μm thick, or greater than 300 μm thick and less than 500 μm thick. Polymerizable recording media with a thickness of less than 300 μm can also be prepared, such as between 50 μm and 300 μm.

Monomers suitable for use in polymerizable media include, for example, those containing epoxide, oxetane, cyclic ether, 1-alkenyl ethers including vinyl ether and 1-propenyl ether, unsaturated hydrocarbon, lactone, cyclic ester, lactam, cyclic carbonate, cyclic acetal, aldehyde, cyclic sulfide, cyclosiloxane, cyclotriphosphazene, or polyol functional groups, and combinations thereof. Epoxides, oxetanes and 1-alkenyl ether functional groups are preferred. A polymerizable medium can contain one or more different polymerizable monomers. The monomers may be monofunctional, difunctional, multifunctional or polyfunctional or combinations thereof.

Monomers suitable for use in holographic recording media typically undergo acid-initiated cationic polymerization (also referred to as “cationic monomers”), such as epoxides or oxetanes. Siloxanes substituted with one or more epoxide moieties are commonly used in holographic recording media. A preferred type of epoxy group is a cycloalkene oxide group, especially a cyclohexene oxide group. Siloxane monomers can be difunctional, such as those in which two or more epoxide groupings (e.g., cyclohexene oxide groupings) are linked to an Si—O—Si grouping. These monomers have the advantage of being compatible with the preferred siloxane binders. Exemplary-difunctional epoxide monomers are those of the formula:

RSi(R¹)₂OSi(R²)₂R (VI),

where each group R is, independently, a monovalent epoxy functional group having 2-10 carbon atoms; each group R¹ is a monovalent substituted or unsubstituted C₁₋₁₂ alkyl, C₁₋₁₂ cycloalkyl, arylalkyl or aryl group; and each group R² is, independently, R¹, or a monovalent substituted or unsubstituted C₁₋₁₂ alkyl, C₁₋₁₂ cycloalkyl, arylalkyl or aryl group. One specific monomer of this type found useful in holographic recording media is that in which each group R is a 2-(3,4-epoxycyclohexyl)ethyl grouping; each grouping R¹ is a methyl group, and each group R² is a methyl group, and which is available from Rhodia Silicones, Rock Hill, S.C., under the trade name S 200. The preparation of this specific compound is described in, inter alia, U.S. Pat. Nos. 5,387,698 and 5,442,026. Additional siloxane monomers are described in PCT Publication No. WO 02/19040 and in U.S. Pat. Nos. 6,784,300 and 7,070,886, the entire teachings of which are incorporated herein by reference.

Siloxane monomers that are suitable for use in holographic recording media can also be polyfunctional. A “polyfunctional” monomer is a compound having at least three groups of the specified functionality, in the present case at least three epoxy groups. The terms “polyfunctional” and “multifunctional” are used interchangeably herein. Polyfunctional monomers have the advantage of being compatible with the preferred siloxane binders and providing for rapid structural buildup and high crosslink density. Polyfunctional monomers suitable for use in holographic recording media typically have three or four epoxides (preferably cyclohexene oxide) groupings connected by a linker through a Si—O group, i.e., a “siloxane group”, to a central Si atom. Alternatively, the epoxides are connected by a linker to a central polysiloxane ring. Alternatively, polyfunctional monomers suitable for use in holography have a plurality of epoxides as pendant groups on a siloxane polymer, copolymer or oligomer.

One example of polyfunctional monomers suitable for use in polymerizable media typically has three or four epoxides (preferably cyclohexene oxide) groupings connected by a linker through a Si—O group, i.e., a “siloxane group”, to a central Si atom. Alternatively, the epoxides are connected by a linker to a central polysiloxane ring. Examples of such polyfunctional monomers are found in U.S. Pat. Nos. 6,784,300 and 7,070,886 and PCT Publication WO 02/19040, the contents of which are incorporated herein by reference in their entirety.

Specific examples of siloxane monomers of this type include the compounds represented by Structural Formulae (VII)-(XI):

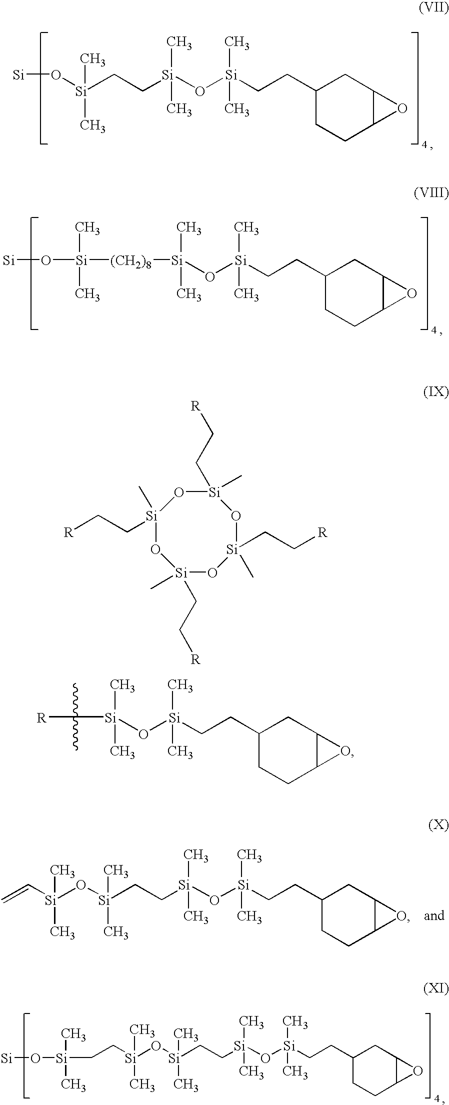

Further description of suitable siloxane monomers can be found in aforementioned U.S. Pat. Nos. 6,784,300 and 7,070,886 and PCT Publication WO 02/19040.

Optionally, the holographic recording medium additionally comprises a second or third monomer that undergoes cationic polymerization or, alternatively, supports cationic polymerization. Optionally, monomers that support cationic polymerization may be essentially inert to cationic polymerization. In one example, the second monomer is a vinyl ether comprising one or more alkenyl ether groupings or a propenyl ether comprising one or more propenyl ether groupings. In another example, the second monomer is a siloxane comprising two or more or three or more cyclohexene oxide groups, as described above. Advantageously, the second monomer is a siloxane having at least two cyclohexene oxide groups and the third monomer is a siloxane having at least two cyclohexene oxide groups. The use of additional monomers is described in U.S. Publication No. US2003/0157414, filed Nov. 13, 1997, the contents of which are incorporated herein by reference in their entirety.

A binder used in the process and preparation of the present medium should be chosen such that it does not inhibit cationic polymerization of the monomers used (e.g., “supports” cationic polymerization), such that it is miscible with the monomers used as well as the polymerized or copolymerized structure, and such that its refractive index is significantly different from that of the polymerized monomer or oligomer (e.g., the refractive index of the binder differs from the refractive index of the polymerized monomer by at least 0.04 and preferably at least 0.09). Binders in this embodiment are not required to increase cohesion in said medium, as is generally the case, and are preferably “diffusible”, but can be substantially or wholly non-diffusible. Diffusible binders can, by way of example, segregate from the polymerizing monomer(s) or oligomer(s) during holographic recording via diffusion-type motion of the binder component. Non diffusible binders can be a monomer(s) or oligomer(s) that is pre-polymerized to form a moderate to high molecular weight polymeric or copolymer structure that supports cationic polymerization and is a substantially non diffusible component relative to the time scale of diffusion processes during holographic recording events. In general, binders can be inert to the polymerization processes described herein or optionally can polymerize (by cationic, free radical or other suitable polymerization) during one or more polymerization events. Preferably, a binder is inert to the polymerization processes of the one or more monomer(s) defined herein and, even more preferably, is diffusible.

Examples of binders for use in holographic recording media are polysiloxanes, due in part to availability of a wide variety of polysiloxanes and the well documented properties of these oligomers and polymers. The physical, optical, and chemical properties of the polysiloxane binder can all be adjusted for optimum performance in the recording medium inclusive of, for example, dynamic range, recording sensitivity, image fidelity, level of light scattering, and data lifetime. The efficiency of holograms produced by the present process in the present medium is markedly dependent upon the particular binder employed. Commonly used binders include poly(methyl phenyl siloxanes) and oligomers thereof, 1,3,5-trimethyl-1,1,3,5,5-pentaphenyltrisiloxane and other pentaphenyltrimethyl siloxanes. Examples are sold by Dow Corning Corporation under the trade name Dow Corning 710 and Dow Corning 705 and have been found to give efficient holograms.

Examples of a diffusible binder having a polymerizable moiety can be found in U.S. Pat. No. 5,759,721, the contents of which are incorporated herein by reference. This patent discloses a siloxane polymer having a number of pendant epoxide (cyclohexene oxide) groups. Specifically, the binder was a poly(methylhydrosiloxane) which was hydrosilated with a 90:10 w/w mixture of 2-vinylnaphthalene and 2-vinyl(cyclohex-3-ene oxide).

Other diffusible binders for use in holographic recording media is that they show favorable molecular miscibility with monomers or oligomers of said media, such as, by way of example, epoxide monomers having low functional group equivalent weight, such as about 200 g/mole epoxide, as well as with those having multifunctionality such as those with functional group equivalent weight of at least 300 g/mole epoxide that are the subject of U.S. Pat. Nos. 6,784,300 and 7,070,886 and PCT Publication WO 02/19040, the teachings of which are incorporated herein.

Further, it is preferable that binders, as a component in holographic recording materials, have a favorable molecular architecture for the reliability and robustness of the holographic recording material such that these binders do not exude or otherwise have deleterious effects upon the optical and/or mechanical properties of the material.

Additionally, said binders should preferably remain substantially soluble or substantially miscible in the holographic material even after substantial polymerization of the monomer(s). Additionally, the holographic recording material should preferably comprise binders such that the recording material is substantially resistant to cracking and/or delamination such as when the material is exposed to elevated temperatures.

Examples of the binders useful for practicing the present invention are those disclosed in co-pending U.S. Pat. Pub. US2007/0042804, filed on Oct. 18, 2006. The entire teachings of this patent application are incorporated by reference herein.

One example of a binder disclosed in US2007/0042804 comprises a siloxane core with at least three high refractive index moieties. E.g., the binder is a multi-armed (at least 3 arms) siloxane core, wherein the terminus of each arm is a high refractive index moiety, as shown in formula (IX) for the case of a star of a siloxane core with four such arms. In formula (IX), Ar is an optionally substituted aryl, connected to the oxygen of the siloxane core by a high refractive index moiety (refractive index of Ar and the moiety should be at least 1.545, more preferably 1.565, still more preferably 1.585).

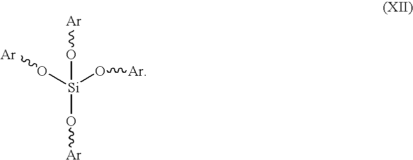

In one embodiment, the wavy line in formula (XII) is an “inert linking group”, wherein an inert linking group is a moiety which: 1) does not react under conditions which induce or initiate cationic polymerization of epoxides; 2) does not interfere with acid initiated cationic polymerization of epoxides; 3) and does not interfere with chemical segregation of the binder of the present invention from polymer formed during cationic polymerization of epoxides.

Other binders disclosed in US2007/0042804 comprise a cyclic methylsiloxane core with pendent aromatic moieties, as shown in formula (XIII), wherein n is the number of methylsiloxane units in the cyclic structure. The cyclic siloxane core comprises at least 3 substituted methylsiloxane units. The cyclic siloxane core of this invention is preferably composed of at least 4 repeat units and more preferably the siloxane core comprises a mixture of ring sizes from n=3 to about n=6 repeat units.

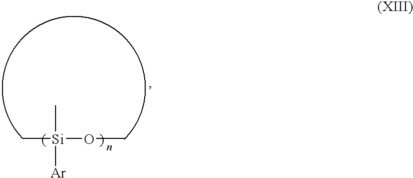

wherein Ar is an optionally substituted aromatic moiety.

In one embodiment the aromatic moieties, depicted as Ar in formula (XIII), are attached directly to the cyclic siloxane core via a bond to Si. In a preferred embodiment the aromatic moiety is attached to the cyclic siloxane core via a linking group X shown below in formula (XIV).

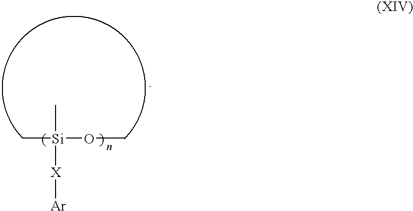

The linking group X is preferably an alkyl group comprising an aliphatic grouping —(CH₂)ₘ— or substituted aliphatic grouping —CHR)ₘ—, where m is a positive integer and R is a substituted or unsubstituted alkyl, cycloalkyl or aromatic grouping (Ar); or the aliphatic grouping —(CH₂)ₘ— or the substituted aliphatic grouping —CHR)ₘ— may be replaced by a substituted or unsubstituted alkylene or cycloalkylene grouping. Additionally the linking group may be an alkenyl group such as would result from the reaction of an arylacetylene, or an arylalkylacetylene, with the cyclic or multi-armed core.

Examples of the binders of formulas (XII), (XIII) and (XIV) include

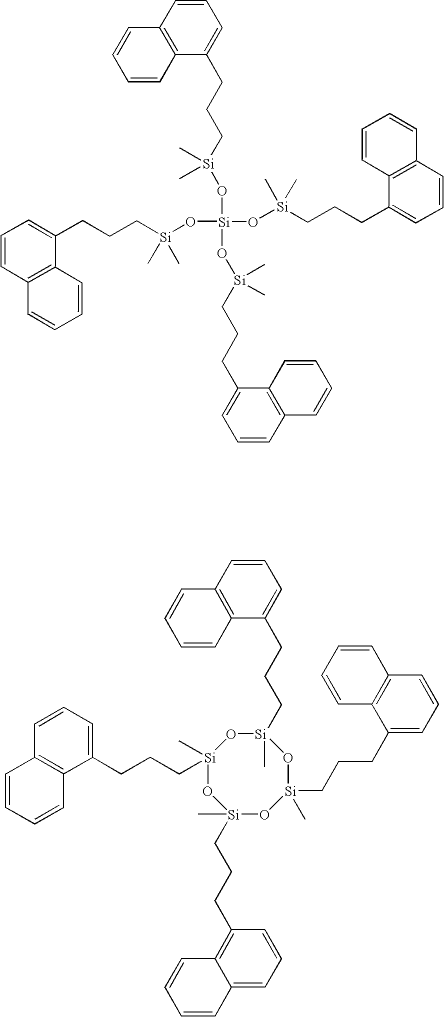

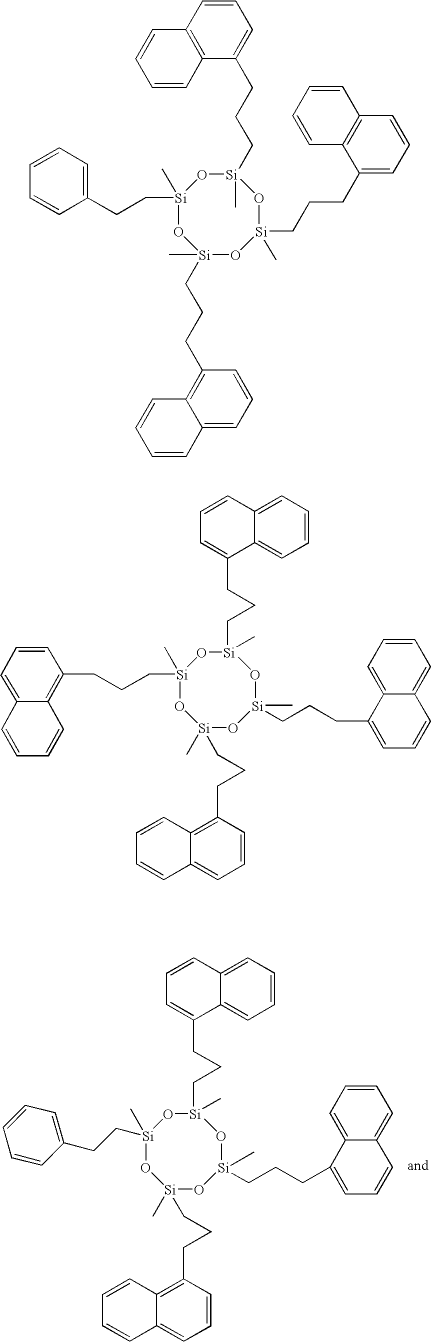

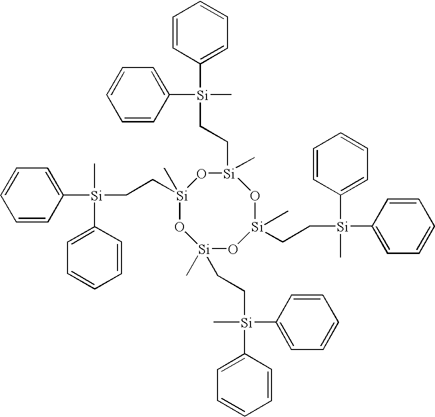

Other examples of a substantially non-diffusible, inert binder can be found in U.S. Pat. Nos. 6,103,454 and 6,165,648, the contents of which are incorporated by reference. Additional examples of a substantially non-diffusible, inert binder can be found in Dhar, et al., Optics Letters, Vol. 24, No: 7, p 487-489, 1999 and Hale, et al., Polymer Preprints, 2001, 42 (2), 793, the contents of which are incorporated herein by reference. In such examples, the binder is a solid polymer matrix formed in situ from a matrix precursor by a curing step (curing indicating a step of inducing reaction of the precursor to form the polymeric matrix). It is possible for the precursor to be one or more monomers, one or more oligomers, or a mixture of monomer and oligomer. In addition, it is possible for there to be greater than one type of precursor functional group, either on a single precursor molecule or in a group of precursor molecules. In the present invention, examples of precursors that support cationic polymerization are typically, but not limited to, those polymerizable by free radical or anionic means and include molecules containing styrene, certain substituted styrenes, vinyl naphthalene, certain substituted vinyl naphthalenes and vinyl ethers, which can optionally be mixed with certain co-monomers.

The proportions of PAG, photosensitizing-dye, monomer(s) or oligomer(s), and binder in holographic recording media of the present invention may vary rather widely, and the optimum proportions for specific components and methods of use can readily be determined empirically by skilled workers. Guidance in selecting suitable proportions is provided in U.S. Pat. No. 5,759,721, the teachings of which are incorporated herein by reference. The solution of monomers with binder can comprise a wide range of compositional ratios, preferably ranging from about 90 parts binder and 10 parts monomer or oligomer (w/w) to about 10 parts binder and 90 parts monomer or oligomer (w/w). It is preferred that the medium comprise from about 0.167 to about 5 parts by weight of the binder per total weight of the monomers for materials comprising moderate concentrations of monomer, whereas for cases of low concentration of monomer (i.e. less than about 10% and in the range of about 3 to 10%) the medium may comprise up to about 32 parts by weight of the binder per total weight of the monomers. Typically, the medium comprises between about 0.005% and about 0.5% by weight dye, and between about 1.0% and about 10.0% by weight PAG.

Acid generated by the method of the present invention can be used in polymerizing one or more polymerizable monomers, as is described above. Such polymerizable monomers can form protective, decorative and insulating coatings (e.g., for metal, rubber, plastic, molded parts or films, paper; wood, glass cloth, concrete, ceramics), potting compounds, printing inks, sealants, adhesives, molding compounds, wire insulation, textile coatings, laminates, impregnated tapes, varnishes, and anti-adhesive coatings. Acid generated by this method can also be used to etch a substrate or to catalyze or initiate a chemical reaction in printed circuit boards or other laser direct imaging processes. A particularly advantageous use of this method is to generate acid uniformly throughout the thickness of the medium in the area of the exposure or illuminated area to maintain optimal physical and optical properties.

An aliphatic group, alone or as a part of a larger moiety, is a hydrocarbon group which can be saturated or unsaturated; branched, straight chained or cyclic; and substituted or unsubstituted. Aliphatic groups of the present invention typically have 1 to about 12 carbon atoms.

An alkyl group, alone or as a part of a larger moiety (alkoxy, alkylammonium, and the like) is preferably a straight chained or branched saturated aliphatic group with 1 to about 1.2 carbon atoms, e.g., methyl, ethyl, n-propyl, iso-propyl, n-butyl, sec-butyl, tert-butyl, pentyl, hexyl, heptyl or octyl, or a saturated cycloaliphatic group with 3 to about 12 carbon atoms.

An alkenyl group, alone or as a part of a larger moiety (e.g., cycloalkene oxide), is preferably a straight chained or branched aliphatic group having one or more double bonds with 2 to about 12 carbon atoms, e.g., ethenyl, 1-propenyl, 1-butenyl, 2-butenyl, 2-methyl-1-propenyl, pentenyl, hexenyl, heptenyl or octenyl, or a cycloaliphatic group having one or more double bonds with 3 to about 12 carbon atoms.

An alkynyl group, alone or as a part of a larger moiety, is preferably a straight chained or branched aliphatic group having one or more triple bonds with 2 to about 12 carbon atoms, e.g., ethynyl, 1-propynyl, 1-butynyl, 3-methyl-1-butynyl, 3,3-dimethyl-1-butynyl, pentynyl, hexynyl, heptynyl or octynyl, or a cycloaliphatic group having one or more triple bonds with 3 to about 12 carbon atoms.

An aryl, alone or as a part of a larger moiety (e.g., diarylammonium) is a carbocyclic aromatic group of 6-14 carbon atoms. Suitable aryl groups for the present invention are those which 1) do not react directly with light in the absence of PAG to initiate or induce cationic polymerization; and 2) do not interfere with acid initiated cationic polymerization. Examples include, but are not limited to, carbocyclic groups such as phenyl, naphthyl, biphenyl and phenanthryl.

Heteroaryl groups, alone or as a part of a larger group, are aromatic groups with 5-14 ring atoms, wherein 1-3 ring atoms are selected from O, N or S. Suitable heteroaryl groups for the present invention are those which 1) do not react directly with light in the absence of PAG to initiate or induce cationic polymerization and 2) do not interfere with acid initiated cationic polymerization. Heteroaryl groups include, but are not limited to, furanyl, thiophene, triarylamino(N-phenylcarbazoyl) and fused polycyclic aromatic ring systems in which a carbocyclic aromatic ring or heteroaryl ring is fused to one or more other heteroaryl rings (e.g., benzofuranyl).

Suitable substituents on alkyl, alkoxy, alkenyl, alkynyl, aryl, heteroaryl and aliphatic groups are those which 1) do not react directly with light in the absence of PAG to initiate or induce cationic polymerization and 2) do not interfere with acid initiated cationic polymerization: Examples of suitable substituents include, but are not limited to C1-C12 alkyl, C6-C14 aryl, —OH, halogen (—Br, —Cl, —I and —F), —O(R′), —O—CO—(R′), —COOH, —N(R′)₂, —COO(R′), —S(R′) and —Si(R′₃). Each R′ is independently a substituted or unsubstituted aliphatic group or a substituted or unsubstituted aryl group. In one embodiment, R′ is an unsubstituted alkyl group or an unsubstituted aryl group. Preferably, R′ is a C1-C12 alkyl, C1-C12 halogenated alkyl, C3-C10 cycloalkyl; more preferably, R′ is methyl, ethyl, 2-ethylhexyl, cyclohexyl, benzyl or a phenyl group. In another embodiment, R′ is a phenyl substituted with one or more substituent groups such as C1-C12 alkyl, C1-C12 halogenated alkyl, C3-C10 cycloalkyl, halogen, phenyl or benzyl, or C1-C12 alkoxy, optionally substituted with C1-C6 alkyl or C1-C6 haloalkyl or C3-C10 cycloalkyl. More preferably, the substituents on phenyl are methyl, ethyl, 2-ethylhexyl, C1-C12 fluorinated or perfluorinated alkyl, cyclohexyl, benzyl, phenyl, 2-ethylhexyloxy, —OCH₃, chloro, or trifluoromethyl.

### EXEMPLIFICATION

### Synthetic Procedure

General: n-Butyllithium (2.5 M in hexanes), lithium phenylacetylide (1 M, THF) and anhydrous THF were all purchased and used as is from Aldrich. All reactions involving organolithium reagents were carried out under nitrogen atmosphere with oven dried glassware. A saturated aqueous solution of tin chloride was made by adding solid tin chloride to a stirring solution of 10% hydrochloric acid until the tin chloride no longer dissolved.

UV-VIS spectra were taken on a Perkin-Elmer Lambda 9 spectrophotometer. HPLC data was collected on an Agilent 1100 series HPLC with UV-VIS diode array detector.

### Example 1

### 1,4-bis-phenylethynylnaphthalene

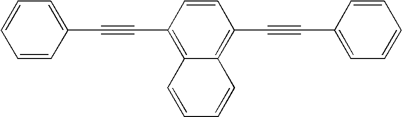

1,4-naphthoquinone (1.0 grams, 6.32 mmol) was dissolved in 20 ml of dry THF giving a clear brown solution. The reaction mixture was cooled to −70° C. Lithium phenylacetylide (15 ml, 15 mmol) was added slowly drop wise over a 20 minute period while maintaining the temperature at −70° C. During this time, the solution turned a dark blue-green color. The reaction was slowly warmed to room temperature and stirred overnight. Upon standing the solution returned to the brown color and developed a tan precipitate. To the stirring reaction mixture was added 10 ml of saturated tin chloride in 10% aqueous HCl. After 30 minutes an additional 10 ml of water was added, yielding formation of a yellow precipitate. The yellow precipitate is filtered off and the resulting filtrate phase separates. The brown organic layer is collected and diluted with dichloromethane and stirred over magnesium sulfate. The solvent is removed by rotary evaporation, leaving a brown solid product. The brown solid and yellow precipitate were combined and dissolved in a minimum amount of dichloromethane. The solution was eluted through silica gel column with 10:1 hexanes/dichloromethane. Fractions obtained from column chromatography containing product are readily identified by the bright blue fluorescent emission. Relevant fractions were combined, solvent removed by rotary evaporation leaving a pale yellow solid. Yield after chromatography was 0.325 grams or 16%.

UV-VIS (320-500 nm, CH₂Cl₂) λₘₐₓ=366 nm, 382.5 nm. ε @405 nm=315

### Example 2

### 1,4-bis-phenylethynyl-2-methoxynaphthalene

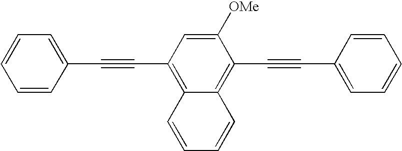

2-methoxy-1,4-napthoquinone (0.5 grams, 2.66 mmol) is dissolved in 20 ml of dry THF. The reaction mixture was cooled to −70° C. The quinone precipitated out but remained stirrable. Lithium phenylacetylide (6 ml, 6 mmol) was added slowly drop wise over a 20 minute period while maintaining the temperature at −70° C. The reaction was slowly warmed to room temperature and stirred overnight. To the stirring reaction mixture was added 10 ml of saturated tin chloride in 10% aqueous HCl. After 30 minutes an additional 10 ml of water was added yielding formation of a yellow precipitate. The yellow precipitate is filtered off and the resulting filtrate phase separates. The brown organic layer is collected and diluted with dichloromethane and stirred over magnesium sulfate. The solvent is removed by rotary evaporation, leaving a brown solid. The brown solid and yellow precipitate were combined and dissolved in a minimum amount of dichloromethane. The solution was eluted through silica gel column with 1:1 hexanes/dichloromethane. Fractions obtained from column chromatography containing product are readily identified by the bright blue fluorescent emission. Relevant fractions were combined, solvent removed by rotary evaporation leaving a pale yellow solid. Yield after chromatography was 0.100 grams or 10%.

UV-VIS (320-500 nm, CH₂Cl₂) λₘₐₓ=377.5 nm, 396.0 nm. ε @405 nm=19,900

### Example 3

### 1,4-bis-(4-methoxyphenylethynyl)naphthalene

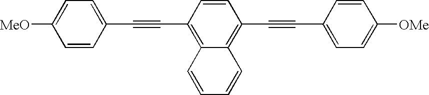

At −70° C., add 2.8 ml of n-butyllithium (2.5 M in hexanes, 6.95 mmol) to a stirring solution of 10 ml THF and 0.9 ml (0.96 g, 7.2 mmol) of ethynylanisole. Allow to warm to room temperature and stir for one hour. 1,4-naphthoquinone (0.5 grams, 3.16 mmol) was dissolved in 20 ml of dry THF giving a clear brown solution. The reaction mixture was cooled to −70° C. The previously made lithium ethynylanisole was added slowly drop wise over a 20 minute period while maintaining the temperature at −70° C., during which the solution turned a dark blue-green color. The reaction was slowly warmed to room temperature and stirred overnight. The solution returned to the brown color and developed a tan precipitate. To the stirring reaction mixture was added 10 ml of saturated tin chloride in 10% aqueous HCl. After 30 minutes an additional 10 ml of water was added yielding formation of a yellow precipitate. The yellow precipitate is filtered off and the resulting filtrate phase separates. The brown organic layer is collected and diluted with dichloromethane and stirred over magnesium sulfate. The solvent is removed by rotary evaporation, leaving a brown solid. The brown solid and yellow precipitate were combined and dissolved in a minimum amount of dichloromethane. The solution was eluted through silica gel column with 1:1 hexanes/dichloromethane. Fractions obtained from column chromatography containing product are readily identified by the bright blue fluorescent emission. Relevant fractions were combined, solvent removed by rotary evaporation leaving a pale yellow solid. Yield after chromatography was 0.600 grams or 50%.

UV-VIS (320-500 nm, CH₂Cl₂) λₘₐₓ=373.5 nm, 392 nm. ε @405 nm=12,200

### Example 4

Preparation of a polymerizable medium with dyes of the present invention, wherein the polymerizable-medium is additionally a Holographic Recording medium.

A photo-polymerizable medium for holographic recording, comprising a naphthalene dye of the present invention (Dye of Example 3) for sensitization of Rhodorsil 2074 (Iodoium salt Photo Acid Generator (PAG) with borate anion available from Rhodia Corporation, Inc.) at 400 to 410 nm, was prepared. A binder of Structural formula (IV), was charged to vessel equipped with a magnetic stir bar. To the binder was added a difunctional epoxide monomer represented by Structural formula (VI):

R′—Si(RR)O—Si(RR)—R′ (VI)

wherein each group R′ is a 2-(3,4-epoxycyclohexyl)ethyl grouping; and each grouping R is a methyl group, and which is available from Polyset Corporation, Inc., Mechanicsville, N.Y., under the trade name PC-1000. The ratio of the binder to the di-functional monomer was 1.46:1.0 wt to wt. The mixture of binder and di-functional monomer was stirred to form a uniform homogeneous mixture. To this mixture was added a poly-functional monomer, referred to herein as C8 tetramer (see U.S. Pat. No. 6,784,300 compound No. XXII), in a ratio of 1.12:1 wt to wt multifunctional epoxy to difunctional monomer, and the contents were stirred at room temperature to form a uniform mixture. A naphthalene dye of the present invention (Dye of Example 3) was added to the uniform mixture of the binder and monomers resulting in a desirable optical density at a concentration of about 0.005% to 0.015% by weight of the final recording medium. The mixture was stirred and heated to 60° C. to dissolve the dye of the present invention. When the dye was completely dissolved the homogeneous mixture was allowed to cool to room temperature. To this mixture was added 6% by weight of the final recording medium of cumyltolyliodonium tetrakis(pentafluorophenyl)borate. The mixture was rapidly stirred until the PAG dissolved, and the formulation was then filtered using an Acrodisc® CR25 mm Syringe filter with a 0.2 micron PTFE Membrane into an appropriate size storage container.

The kinetics and extent of photopolymerization exhibited by the holographic recording materials were obtained by calorimetric analysis using a Perkin-Elmer DSC-7 Differential Scanning Calorimetry (see Waldman et al., J. Imaging Sci. Technol. 41, (5), pp. 497-514, (1997)) equipped with a DPS-7 photocalorimetric module comprising a monochromator that was operated for wavelength of 407 nm. The values obtained for onset of exothermicity, time to peak exothermicity, and enthalpy of photopolyermization due to the photopolymerization reactions sensitized at the wavelength of 407 nm, were comparable and consistent with values reported previously in U.S. Pat. No. 6,881,464 for the photopolymerization of the same mixture of monomers at the wavelength of 532 nm. The optical density (OD) of the holographic recording materials was measured with a Perkin-Elmer Lambda9 spectrophotometer for each formulation in a 1 mm path cell.

A card type media was prepared by first fixing two flat glass substrates disposed in a parallel, coplanar arrangement with a space or gap of −300 microns between the inner surfaces of the top and bottom substrates. Examples of methods for media assembly can be found in U.S. Pat. No. 6,881,464, the entire teachings of which are incorporated herein. The formulation was coated between the two substrates using capillary forces. After complete filling of the “gap” the media was ready for further analysis.

Co-locational slant fringe plane-wave, transmission holograms were recorded in the conventional manner with a semiconductor violet laser with external cavity emitting at λ=407 nm, available from Sony Corp., using two coherent spatially filtered and collimated laser writing beams directed onto the sample with an interbeam angle of 51°. The intensities of the two writing beams were substantially equal at the condition of equal semiangles about the normal, and the total incident intensity for recording was 5.6 mW/cm² as measured at the bisecting condition. The sample was mounted onto an optically encoded motorized rotation stage, Model 495 from Newport Corporation, for rotation of φ about the perpendicular to the face of the sample in the interaction plane, and this stage was mounted onto an optically encoded motorized rotation stage, 496B from Newport Corporation, for rotation of θ about the vertical axis denoted as the y-axis. Multiplexed co-locational plane-wave transmission holograms were recorded by combining azimuthal and planar-angle multiplexing (see method of Waldman et al., J. Imaging Sci. Technol. 41, (5), pp. 497-514, (1997)). Azimuthal multiplexing was carried out via rotations of Δφ about an axis perpendicular to the surface plane of the sample (i.e. z-axis at the condition of equal semiangles for the writing beams) and through the x-y center of the imaged area for a specific value of θ, where θ denotes the rotational position of the sample plane about the y-axis, said axis being perpendicular to the interaction plane. Angle multiplexing was carried out in the standard manner by rotation of Δθ which defines Ω₁ and Ω₂, the external signal and reference writing beam angles, respectively, and thus the grating angle for the plane-wave holograms. Values of φ were limited to the range of 0°≦φ<180° and Δφ was 1.5°, thus corresponding to 120 co-locational recordings, respectively, for each of the first three grating angle conditions specified by θ having the value of −16°, or −10°, or −4° (counterclockwise rotation) from the bisector condition for the two writing beams. Additionally, a last cycle of 23 holograms was recorded, after a total of 360 were recorded during the first three cycles, by incrementing Δφ by 8° for θ having the value −7.0°. The length of the exposure times was controlled via a direct serial computer interface to a Newport 846HP mechanical shutter and a recording schedule was used that ramped exposure times to longer values in monotonic fashion in accordance with the monotonic decline in recording sensitivity that is exhibited by the recording material.

Reconstruction of the 383 co-locationally multiplexed plane-wave gratings was accomplished by utilization of reading beams that corresponded to the recording beams, but with an incident irradiance, measured at normal incidence to the sample, of 3.0 mW/cm². Diffraction intensity data was obtained for all 383 co-locationally recorded holograms, after completion of the recording of the multiplexed holograms, using two Model 818-SL/CM photodiodes and a Model 2835-C dual channel multi-function optical meter from Newport Corporation. Apertures were placed on the face of the photodiode detectors to ensure that diffraction from only one azimuthal angle condition was detected for each Bragg angle (i.e. increment of θ) that was interrogated. The read angle was tuned to the optimum Bragg condition (i.e. value for maximum diffraction efficiency) for each θ, φ combination used in the multiplexing sequence by rotation of the media about the y-axis for a given value of φ, and the diffraction efficiency was measured at each Δθ angular increment of 0.005° to 0.01° for each θ, φ combination to obtain accurate Bragg detuning profiles for each multiplexed hologram.

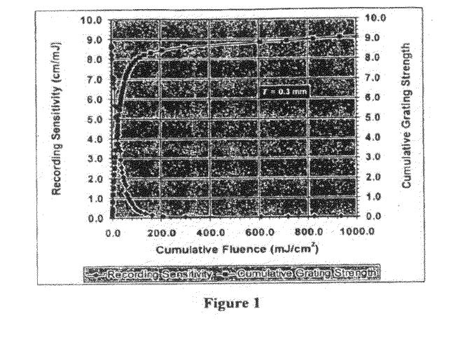

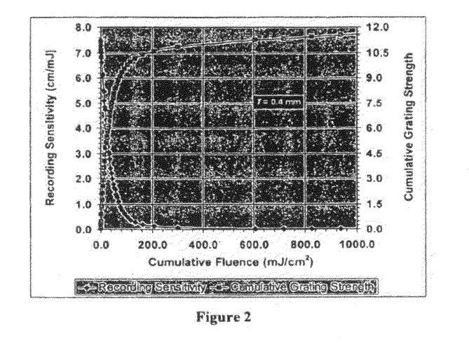

FIG. 1 shows recording sensitivity in cm/mJ, as determined from the measured values of diffraction efficiency, ηᵢ, of each hologram, as a function of cumulative exposure fluence in mJ/cm² for a holographic recording material of thickness, T=300 microns. Sensitivity in cm/mJ is calculated in the standard manner as (ηᵢ^{0.5}/Iᵢ*tᵢ)T, where T is thickness of the recording material, tᵢ is the length of the recording time for the ith recording event, and Iᵢ is the intensity for the recording event. The recording sensitivity for the holographic recording medium comprising a naphthalene dye (sensitizer) of the present invention declined with nonlinear dependence on cumulative recording fluence from a high of about 8.8 to a value of 0.5 cm/mJ after a cumulative exposure fluence of about 90 mJ/cm². FIG. 1 also shows the cumulative grating strength attained as a function of cumulative recording fluence, reaching a value of about 9 for a volume shrinkage condition of the material that is about ≦0.1%. About 86% of the final value for cumulative grating strength was attained over the cumulative exposure fluence of only 90 mJ/cm². FIG. 2 shows recording sensitivity in cm/mJ and cumulative grating strength, determined from the measured values of diffraction efficiency, ηᵢ, of each hologram, as a function of cumulative exposure fluence in mJ/cm² for a holographic recording material comprising a naphthalene dye (sensitizer) of the present invention of thickness, T=400 microns. The recording sensitivity for the holographic recording medium of T=400 microns declined with nonlinear dependence on cumulative recording fluence from a high of about 7.5 to a value of 0.5 cm/mJ after a cumulative exposure fluence of about 100 mJ/cm². The cumulative grating strength attained as a function of cumulative recording fluence, achieves a value of about 11.6 for a volume shrinkage condition of the material that is about ≦0.1%.

The recording sensitivity and grating strength exhibited by use of a sensitizer of the present invention at 407 nm is greater than achieved with similar recording materials of the same thickness when sensitized for recording at 532 nm, when comparing at the same value of volume shrinkage. This is a consequence of increased grating strength at 407 nun due to the expected 1/λ dependance, and further due to the effect of dispersion in refractive index of the monomer(s) versus binder(s) as a function of decreasing the wavelength that thereby increases achieved refractive index modulation.

While this invention has been particularly shown and described with references to preferred embodiments thereof, it will be understood by those skilled in the art that various changes in form and details may be made therein without departing from the scope of the invention encompassed by the appended claims.

1-21. (canceled)

22. A holographic recording medium, wherein said medium comprises:
a) a dye represented by Structural Formula (I): 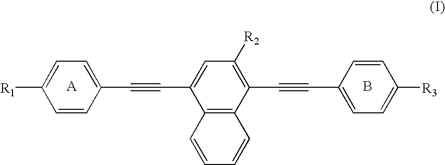
wherein:
R₁ and R₃, are each independently —H, a halogen, a substituted or unsubstituted alkyl group, a substituted or unsubstituted alkenyl group, a substituted or unsubstituted alkoxy group, a substituted or unsubstituted aryl group, a substituted or unsubstituted heteroaryl group, or —Si(R₅)₃;
R₂ is —H, is a substituted or unsubstituted alkyl group, a substituted or unsubstituted alkenyl group, a substituted or unsubstituted alkoxy group, a substituted or unsubstituted aryl group, or a substituted or unsubstituted heteroaryl group, or —Si(R₅)₃;
R₅ is a substituted or unsubstituted alkyl group or a substituted or unsubstituted aryl group or a substituted or unsubstituted heteroaryl group; and
wherein ring A and ring B, in addition to R₁ or R₃, are each independently further optionally substituted with one or more substituents selected from the group consisting of halogen, substituted or unsubstituted alkyl, substituted or unsubstituted alkoxy, trialkylammonium and diarylamino groups, wherein each alkyl, and each aryl is independently optionally substituted;
b) a compound, referred to as a “PAG,” which in combination with the dye produces acid when exposed to actinic radiation;
c) a monomer or oligomer which is capable of undergoing cationic polymerization initiated by the acid; and
d) a binder that is capable of supporting cationic polymerization of the monomer or oligomer.

23. The holographic recording medium of claim 22, wherein the dye represented by Structural Formula (II): 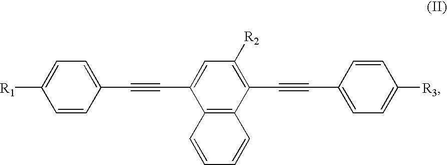
wherein:
R₁ and R₃, are each independently —H, a halogen, a substituted or unsubstituted alkyl group, a substituted or unsubstituted alkenyl group, a substituted or unsubstituted alkoxy group, a substituted or unsubstituted aryl group, or a substituted or unsubstituted heteroaryl group; and
R₂ is substituted or unsubstituted alkyl groups, substituted or unsubstituted alkenyl groups, substituted or unsubstituted alkoxy groups, substituted or unsubstituted aryl groups, a substituted or unsubstituted heteroaryl group, or —H.

24. The holographic recording medium of claim 22, wherein said medium is greater than about 300 μm thick.

25. The holographic recording medium of claim 22, wherein said medium is greater than 500 μm thick.

26. The holographic recording medium of claim 22, wherein said medium is greater than 1,000 μm thick.

27. The holographic recording medium of claim 22, wherein the PAG is a sulfonium, iodonium, diazonium or phosphonium salt and wherein the medium has a thickness of greater than 100 μm.

28. (canceled)

29. The holographic recording medium of claim 22, wherein R₂ is —H or a substituted or unsubstituted alkoxy group.

30. The holographic recording medium of claim 29, wherein R₁ and R₃ are —H or a substituted or unsubstituted alkoxy group.

31. (canceled)

32. The holographic recording medium of claim 30, wherein R₂ is —H or —OCH₃.

33. The holographic recording medium of claim 29, wherein R₁ and R₃ are —H or —OCH₃ and R₂ is H.

34. The holographic recording medium of claim 22, wherein the binder is diffusible and inert to polymerization.

35. The holographic recording medium of claim 22, wherein the monomer is an epoxide monomer.

36. The holographic recording medium of claim 35, wherein the epoxide monomer comprises cyclohexene oxide groups.

37. The holographic recording medium of claim 36, wherein the epoxide monomer is a siloxane comprising two or more cyclohexene oxide groups.

38. The holographic recording medium of claim 36, wherein the epoxide monomer is a polyfunctional siloxane comprising three or more cyclohexene oxide groups.

39. The holographic recording medium of claim 22, wherein the medium comprises a second monomer or oligomer capable of undergoing cationic polymerization.

40. The holographic recording medium of claim 22, wherein the salt is an iodonium salt selected from the group consisting of (4-octyloxyphenyl)phenyliodonium hexafluoroantimonate, ditolyliodonium tetrakis(pentafluorophenyl)borate, diphenyliodonium tetrakis(pentafluorophenyl)borate, tolylphenyliodonium tetrakis(pentafluorophenyl)borate, cumyltolyliodonium tetrakis(pentafluorophenyl)borate, di(4-t-butylphenyl)iodonium tris(trifluoromethylsulfonyl)methylate, dicumyliodonium tetrakis(3,5-bistrifluoromethylphenyl)borate, di(4-t-butylphenyl)iodonium tetrakis(3,5-bistrifluoromethylphenyl)borate and cumyltolyliodonium tetrakis(3,5-bistrifluoromethylphenyl)borate.

41-53. (canceled)

54. A method of recording holograms within a holographic recording medium wherein the medium comprises:
a) a dye represented by following structural formula: 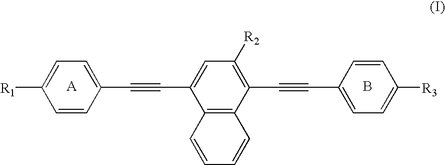
wherein:
R₁ and R₃, are each independently —H, a halogen, a substituted or unsubstituted alkyl group, a substituted or unsubstituted alkenyl group, a substituted or unsubstituted alkoxy group, a substituted or unsubstituted aryl group, a substituted or unsubstituted heteroaryl group, or —Si(R₅)₃;
R₂ is —H, a substituted or unsubstituted alkyl group, a substituted or unsubstituted alkenyl group, a substituted or unsubstituted alkoxy group, a substituted or unsubstituted aryl group, or a substituted or unsubstituted heteroaryl group, or —Si(R₅)₃;
R₅ is a substituted or unsubstituted alkyl group or a substituted or unsubstituted aryl group or a substituted or unsubstituted heteroaryl group; and
wherein ring A and ring B, in addition to R₁ or R₃, are each independently further optionally substituted with one or more substituents selected from the group consisting of halogen, substituted or unsubstituted alkyl, substituted or unsubstituted alkoxy, and trialkylammonium and diarylamino groups, wherein each alkyl, and each aryl is independently optionally substituted;
b) a compound, referred to as a “PAG,” which in combination with the dye produces acid when exposed to actinic radiation;
c) a monomer or oligomer which is capable of undergoing cationic polymerization initiated by the acid; and
d) a binder that is capable of supporting cationic polymerization of the monomer or oligomer,
said method comprising the step of passing into the medium a reference beam of coherent actinic radiation and an object beam of the same coherent actinic radiation, thereby forming within the medium an interference pattern, such that the PAG is capable of producing acid upon exposure to the actinic radiation, and the monomer or oligomer is capable of undergoing cationic polymerization initiated by the acid and thereby recording a hologram within the medium.

55. The method of claim 54, wherein the dye is represented by Structural Formula (II): 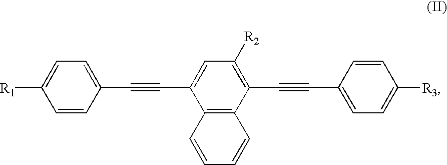
wherein:
R₁ and R₃, are each independently —H, a halogen, a substituted or unsubstituted alkyl group, a substituted or unsubstituted alkenyl group, a substituted or unsubstituted alkoxy group, a substituted or unsubstituted aryl group, a substituted or unsubstituted heteroaryl group;
R₂ is substituted or unsubstituted alkyl groups, substituted or unsubstituted alkenyl groups, substituted or unsubstituted alkoxy groups, substituted or unsubstituted aryl groups, a substituted or unsubstituted heteroaryl group, or —H.

56. The method of claim 54, wherein the compound which produces acid when exposed to actinic radiation is a sulfonium, iodonium, diazonium or phosphonium salt.

57. The method of claim 54, wherein the medium has a thickness of greater than 100 μm.

58. The method of claim 55, wherein R₂ is —H or a substituted or unsubstituted alkoxy group and, optionally, wherein R₁ and R₃, are —H or a substituted or unsubstituted alkoxy group.

59. (canceled)

60. The method of claim 58, wherein R₂ is —H.

61. The method of claim 58, wherein R₂ is —OCH₃.

62. The method of claim 58, wherein R₁ and R₃ are —OCH₃ and R₂ is —H.
